(19) United States
(12) Patent Application Publication
(10) Pub. No.: US 2008/0155157 A1
(43) Pub. Date: Jun. 26, 2008

(54) Hot-swappable multi-configuration modular network service system

(76) Inventor: Dan Lee, Burnaby (CA)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/643,423

(22) Filed: Dec. 20, 2006

(51) Int. Cl. G06F 13/00; H05K 7/10

(52) U.S. Cl. 710/301; 710/302

(57) ABSTRACT

A method and apparatus for a hot swappable media interface card capable of layer-1 processing is described. The media interface card transmits and receives physical layer network traffic with a main board. The main board performs media access control layer transformation.

### FIELD OF THE INVENTION

The present invention relates generally to network communication equipments. More particularly, this invention relates to a network service system comprising a hot-swappable multi-configuration physical layer media interface card and a main board.

### BACKGROUND

Broadband network deployment demands multi-service broadband aggregation platforms specifically architected and optimized to deliver high-demand and high throughput services. For example, a triple-play broadband service encompasses video, voice, data and interactive content delivery. Typical solutions for such service are only available in a higher-density, high-cost, chassis-based arrangement. In a smaller network environment such as distributed points of presence (POPs), remote central officers (RCOs) or multi-tenant units (MTUs), such solutions are not only economically infeasible, but also difficult to deploy. In addition, expanding of an established network may require the purchasing of additional equipments while prematurely rendering the current equipment investments obsolete.

Therefore, the challenges for network service providers are to find a comprehensive network infrastructure solution that a) embraces the latest network technology, b) has deployment flexibility, c) has operational and financial efficiencies, d) has space-saving efficiency, e) is scalable beyond the centralized hub architecture, and f) can accommodate new technologies. Furthermore, in order to, to reduce maintenance and to maximize network uptime, hot-swapping is an important capability that allows the network administrator to quickly expand capacity or to replace faulty component without interrupting or degrading network performances. However, a challenge of incorporating the hot-swapping technology into any system configuration is the locating of the optimal degree of modularity in network architecture in order to achieve maximum flexibility with minimum expenses.

FIG. 1 is a block diagram illustrating one embodiment of a typical network protocol hierarchy. Each of network layers 102, 104, 106, and 108 within FIG. 1 is built upon the one below it. The purpose of each layer is to offer certain network services, while hiding the detail implementation of these network services, to the higher layers. Each layer passes data and control to the layer below or above for further processing. Interfaces between each layer define types of services and data structures the lower layer offers to the immediate upper one. A clearly defined interface not only optimizes the amount of information passes between layers, but also simplifies the replacement of one layer implementation with another implementation in providing the same services. The actual network communication between hosts on a network occurs through the physical medium 108. While in one embodiment physical medium 108 is a wired connection using copper wires or optical fibers, in alternate embodiments, physical medium 108 is a different connection (wireless communication through radio or infrared waves, etc.)

In addition, FIG. 1 illustrates a typical network protocol model similar to transmission control protocol/internet protocol (TCP/IP) reference model. Application layer 102 comprises various network applications such as email applications, web browsers, etc. that utilize high level protocols, such as TELNET, file transfer protocol (FTP), hyper text transfer protocol (HTTP), etc. Application layer 102 depends on transport Layer 104 to maintain a network conversation with the remote network peers. The basic function of transport layer 104 is to accept data from application layer 102 above or network layer 106 below, prepare the data for the next layer and pass the data to the next layer. If transport layer 104 receives application data from the application layer, transport layer 104 breaks the application data into units of data or packets, and passes these packets to network layer 106. On the other hand, if transport layer 104 receives packets from network layer 106, transport layer orders these received packets into application data, and returns the completed application data to application layer 102.

One function of the network layer 106, sometimes referred to as Media Access Control (MAC) layer, is to prepare the packets received from the transport layer 104 so the packets can effectively and independently travel through any network. To ensure the successful delivery of the packets, network layer 106 overcomes the differences among heterogeneous networks by breaking the packet data into data frames and passing the data frames to physical layer 108. Physical layer 108 maintains the integrity of the data frames transmitted and received without any regard to the content of the data frames. Furthermore, physical medium 108 physically transmits network signals through physical medium 110, as well as providing physical layer 108 also provides data flow regulation and error handling functions

FIG. 1B is a block diagram of a typical chassis-based router 120. A typical chassis-based router 120 comprises a chassis 126 coupled to line cards 122A-N and processing cards 124A-B. Line cards 122A-N forward packets based on layer-2 or layer-3 information contained in the packets. Processing cards 124A-B process route changes, manage subscription information, etc. Because line cards process packets based on layer-2 or layer-3 information, each line card include a control processor to process the packets.

### BRIEF SUMMARY

A method and apparatus for a hot swappable media interface card capable of layer-1 processing is described. The media interface card transmits and receives physical layer network traffic with a main board. The main board performs media access control layer transformation.

The claimed invention is directed to a multi-configuration Physical Layer media interface card hot-swappable from a main board. In one embodiment, the media interface card comprises a network connector, a media interface card interface connector, and a physical layer device. The media interface card interface connector has hot swap support so that the media interface card can be hot-swapped into a main board during the runtime. The physical layer device provides Physical Layer (Layer-1) interfacing to the network messages passing through the network connector and the main board. The network connector supports various media types and standards.

In another embodiment, the main board comprises a main board interface connector and a MAC layer device. The media interface card interface connector has hot swap support so that the media interface card can be hot-swapped into a main board during the runtime. The MAC layer performs MAC layer transformation on the network traffic received from or transmitted to the media interface card.

Other features of the present invention will be apparent from the accompanying drawings and from the detailed description which follows.

### BRIEF DESCRIPTION OF THE DRAWINGS

The present invention is illustrated by way of example and not limitation in the figures of the accompanying drawings in which like references indicate similar elements.

FIG. 1A (Prior Art) is a block diagram illustrating a typical network protocol hierarchy.

FIG. 1B (Prior Art) is a block diagram illustrating a typical chassis based router.

FIG. 1C is a block diagram of a network element according to embodiment of the invention.

FIG. 2 is a block diagram illustrating network configuration according to one embodiment of the invention.

FIG. 3 is a block diagram of a Media Interface Card configuration according to one embodiment of the invention.

FIG. 4 is a block diagram of a Main Board configuration according to one embodiment of the invention.

FIG. 5 is a block diagram of a Media Interface Card configuration according to an alternative embodiment of the invention.

FIG. 6 is a block diagram of a Media Interface Card configuration according to another alternative embodiment of the invention.

FIG. 7 is a block diagram of a Media Interface Card coupling with a Main Board according to one embodiment of the invention.

FIG. 8A is a block diagram illustrating one example of a Media Interface Card according to one embodiment of the invention.

FIG. 8B is a block diagram illustrating one more example of a Media Interface Card according to one embodiment of the invention.

FIG. 9A is a block diagram illustrating one more example of a Media Interface Card according to one embodiment of the invention.

FIG. 9B is a block diagram illustrating one more example of a Media Interface Card according to one embodiment of the invention

FIG. 10 is a flow diagram illustrating a process of hot-plugging a Media Interface Card onto a Main Board, according to one embodiment of the invention.

FIG. 11 is a flow diagram illustrating a process for hot-unplugging a Media Interface Card from a Main Board, according to one embodiment of the invention.

FIG. 12 is an illustration of certain components of a Media Interface Card, according to one embodiment of the invention.

### DETAILED DESCRIPTION

A hot-swappable, multi-configuration network system and its components are described herein. In the following description, numerous details are set forth to provide a more thorough explanation of embodiments of the present invention. It will be apparent, however, to one skilled in the art, that embodiments of the present invention may be practiced without these specific details. In other instances, well-known structures and devices are shown in block diagram form, rather than in detail, in order to avoid obscuring embodiments of the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification do not necessarily all refer to the same embodiment.

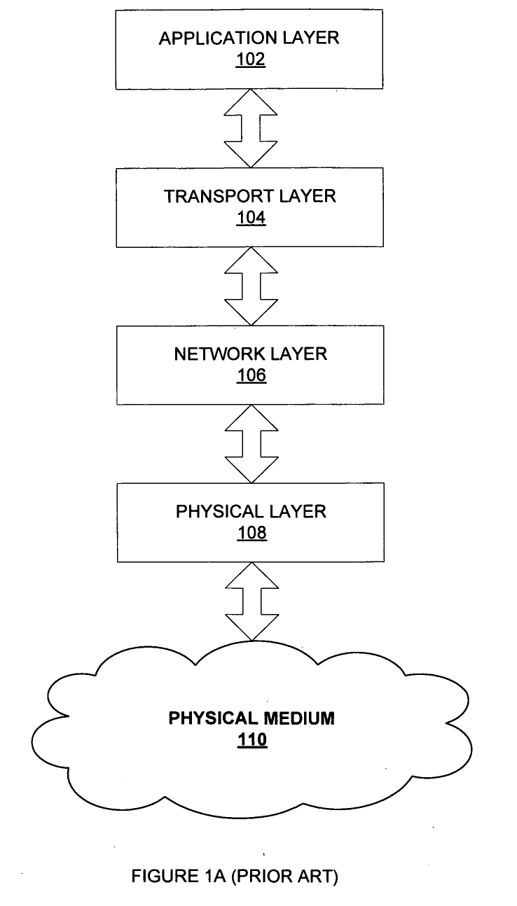

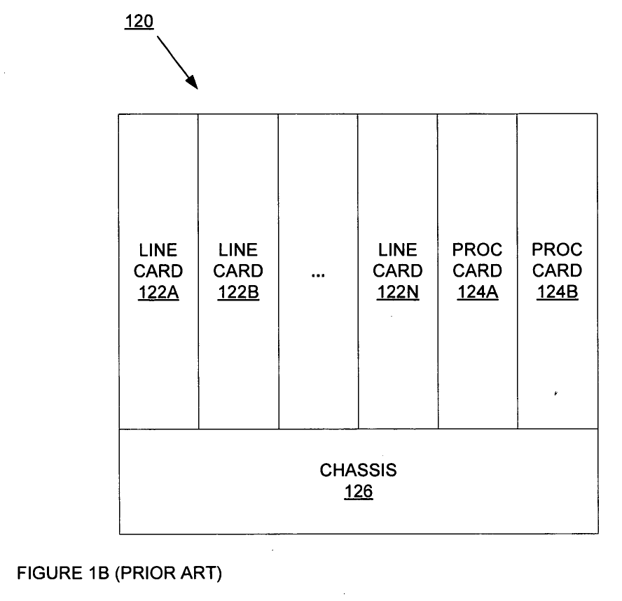

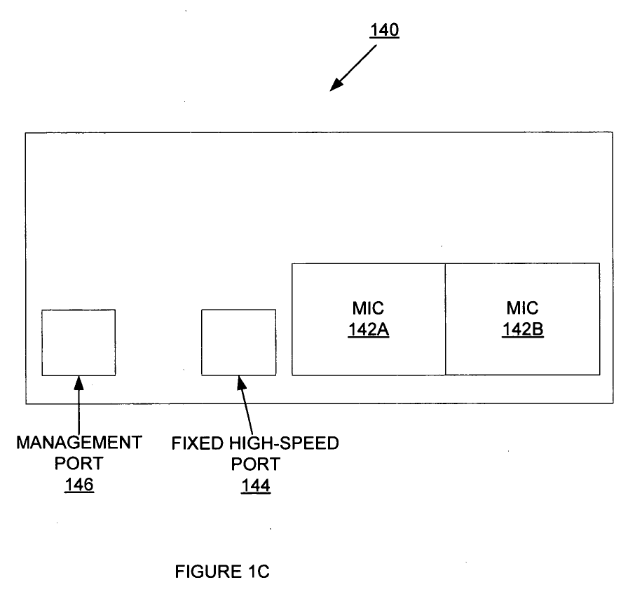

According to certain embodiments of the invention, a modular design of a network element comprising a media interface card coupling with a main board that allows for easier integration of new technology and permits the mixing of different media access technologies in a single unit is described. FIG. 1C is a block diagram of a network element 140 according to one embodiment of the invention. In FIG. 1C, network element 140 comprises media interface card (MIC) 142A-B, fixed high speed port 144, and local management port 146. While in this embodiment, FIG. 1C illustrates network element 140 with a MICs 142A-B, two fixed high speed port 144, and one local management port 146, port alternate embodiments may have more, less and/or different configurations of high-speed low-speed port management ports and MICs. Furthermore, an alternate embodiment may have in addition, wireless ports.

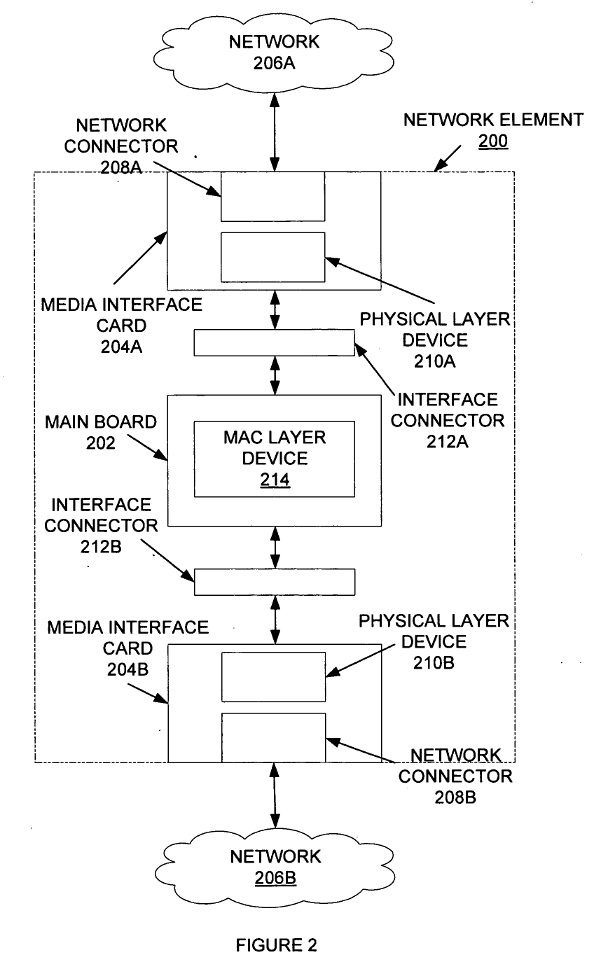

FIG. 2 is a block diagram illustrating network element 200 according to one embodiment of the invention. In FIG. 2, network element 200 comprises main board 202 coupled to two media interface cards (MIC) 204A-B through interface connector 212A-B. MICs 204A-B further couple to network 206A-B. While this embodiment illustrates network element 200 comprising two MICs coupled to two networks, in alternate embodiments network element 200 may have one or more MICs coupled to one or more networks or a single MIC that couples to one or more networks.

Main board 202 provides a platform for sophisticated network services such as, but not limited to, edge routing, Ethernet aggregation and advanced subscriber management. Main board 202 comprises MAC layer device 214 and couples to flexible interface connectors 212A-B, which support multiple modular interface options. While in one embodiment, main board 202 has two interface connectors 212A-B, in alternate embodiments, main board 202 can more or less interface connectors. Interface connectors 212A-B do not need to be coupled to MIC 204A-B for main board 202 to be functional. For example and by way of illustration, in one embodiment, main board 202 couples to fixed high speed port 144 to process network traffic received and transmitted through fixed high speed port 144. One or more MICs 204A-B can be added through the interface connectors 212 which provide configurability and expandability to main board 202. MAC layer device 214 performs network layer transformation.

MICs 204A-B comprise a physical layer device 210A-B capable of performing physical layer transformation on the network messages passing through MIC 204A-B. In one embodiment, MICs 204A-B convert network signal received from networks 206A-B into layer-1 data frames. These data frames are forwarded to main board 202 by MICs 204A-B through the appropriate interface connector 212A-B. In this embodiment, main board 202 converts the data frames into higher layer packets and processes these packets based on layer 2 or higher processing. Thus, MICs 204A-B are a layer-1 interface card. This contrasts with the prior art, where a chassis-based router employ line cards that process the received packets based on the layer-2 (or higher) information contained in the packet. As is described below, embodiments of MICs are hot-swappable, are configurable to support multiple port speeds and media types and have a simplified control/data infrastructure.

Each MIC 202A-B further comprises one or more network connector 208A-B capable of being coupled to hosts (not shown) on network 206A-B. Hosts from network 206A-B transmit network communications through the network connector 208A-B to MIC 204A-B. Physical layer device 210A-B in MIC 204A-B processes the received network communications and sends the processed network data to main board 202 through interface connector 212A-B. MAC layer device 214 and other devices on main board 202 further process the received network data according as needed. Physical layer device 210A-B in MIC 204A-B processes the data received from main board 202 and transmits the data to a recipient host on network 206A-B through the network connector 208A-B. Network data processed by main board 202 may pass through the same MIC card, or through different MIC 202A-B attached to main board 202 according to the network traffic forwarding policies.

In addition, MICs 204A-B may be hot-swapped with main board 202 during run-time, enabling main board 202 to be cost-effectively expanded and/or quickly reconfigured with no platform downtime. Hot-swapping or hot-plugging is commonly referred to the ability to add or remove an electronic component of a computer or system without shutting down the power to the computer or system. The hot-swapping enabled system or component requires sophisticated software and hardware support in order to achieve the plugging and unplugging during live operation. As a result, such an embodiment of the invention could achieve the highest flexibility in terms of costs and maintenances

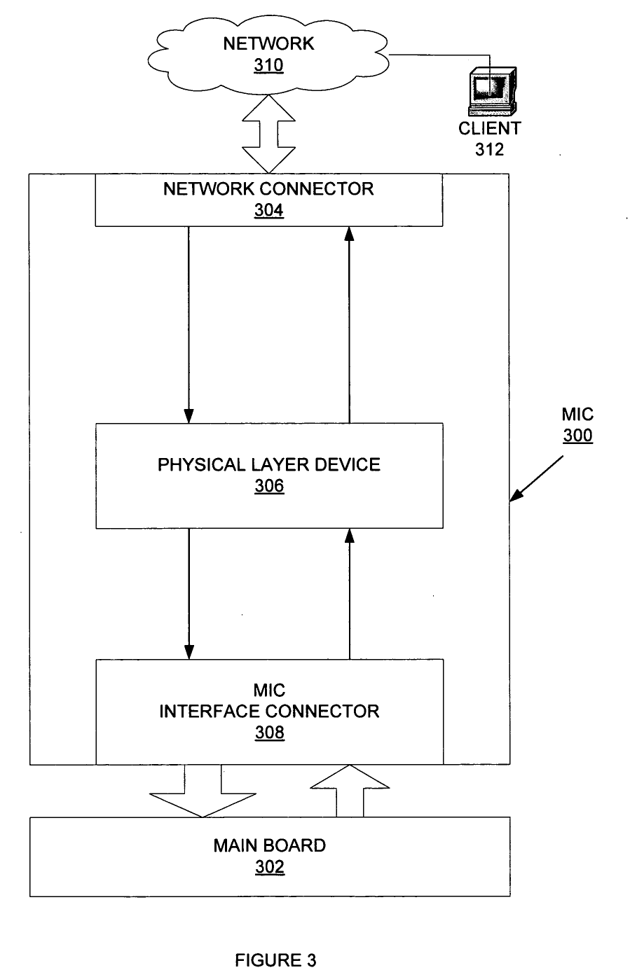

FIG. 3 is a block diagram illustrating MIC 300 configuration according to one embodiment of the invention. In this example, MIC 300 is plugged into main board 302 through MIC interface connector 308. MIC 300 comprises network connector 304 capable of being coupled to a client over a network, MIC interface connector 308 capable of being hot-swapped from main board 302, and physical layer device 306. In an inflow network communication situation, network connector 304 receives raw network signals from network 310 and passes the network signals to physical layer device 306. In certain situation, one form of network signals may be transformed into another form before passing to physical layer device 306. Client 312 typically transmits the network communication into data frames (from several hundreds to several thousands bytes), and transmits the data frames sequentially. These data frames are typically transmitted by the network signal. Physical layer device 306 constructs data frames from the network signals by digitizing the received network signals. The data frames are sent to main board 302 through MIC interface connector 308.

In this example, main board 302 transmits network messages in data frames to the physical layer device 306 through MIC interface connector 308. Physical layer device 306 converts the digitized data frames into raw network signals and sends these network signals to client 312 via network connector 304 and network 310. In certain embodiments of the invention, in addition to the transmitting and receiving functions, physical layer device 306 provides status and assessment functions to detect the start of a network signal or to determine whether the physical medium is clear prior to transmission.

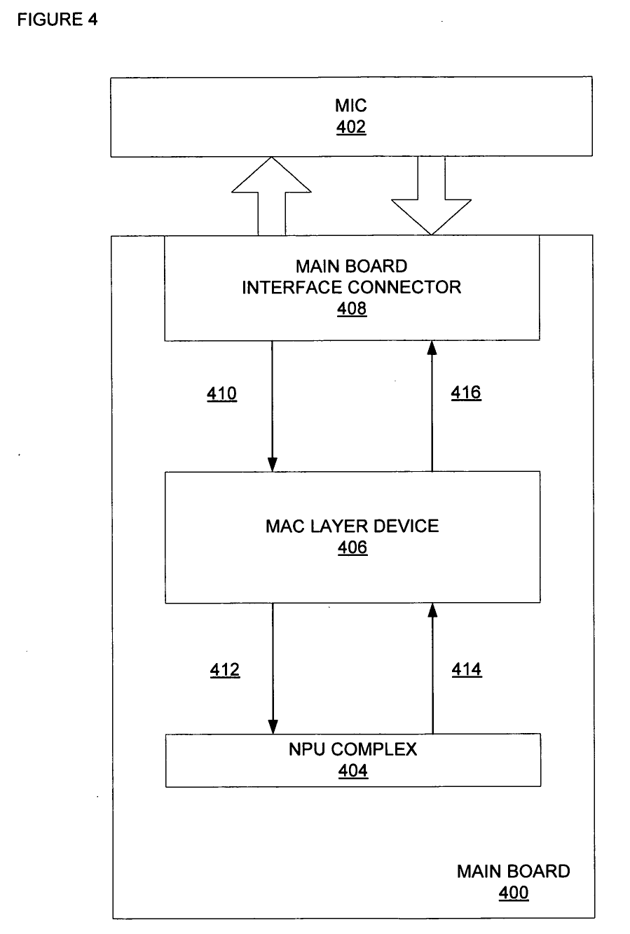

FIG. 4 is a block diagram illustrating a main board 400 configuration according to one embodiment of the invention. Main board 400 comprises MAC layer device 406 coupled to both main board interface connector 408 and Network Processing Unit (NPU) 404. In addition, main board interface connector 408 couples to MIC 402.

MIC 402 transmits inflow data frames, which are referred to in FIG. 3 as data frames, to main board 400 through the main board interface connector 408. MAC layer device 406 recognizes the inflow data frames based on the beginning and ending in the bit-stream received. Furthermore, MAC layer device 406 may also perform error detection, duplication or filtering functions.

In another embodiment, MAC layer device 406 processes the inflow data frames 410 into data packets 412 before sending the data packets 412 to the NPU Complex 404 for further processing. Similarly, NPU Complex 404 passes outflow data packets 414 to MAC layer device 406. MAC Layer Device 406 delimits the frames and transmits the data as outflow data frames 416 to MIC 402 through the main board interface connector 408. NPU 404 processes data packets 412 based on layer 2 or higher processing.

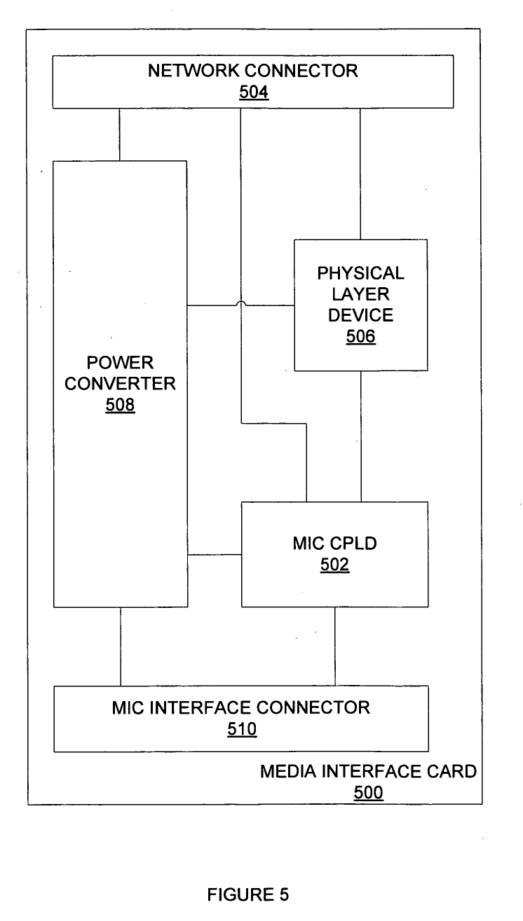

FIG. 5 is a block diagram illustrating MIC 500 configuration according to another embodiment of the invention. MIC 500 comprises power converter 508, MIC Complex Programmable Logic Device (CPLD) 502, physical layer device 506, network connector 504, and MIC interface connector 510. Power converter 508 couples to physical layer device 506, network connector 504, and MIC interface connector 510. Physical layer device 506 further couples to network connector 504, MIC interface connector 510 and MIC CPLD 502. In addition, MIC CPLD 502 couples to MIC interface connector 510 and network connector 504.

Power converter 508 receives electronic power from main board 202 through MIC interface connector 510 and converts the power into different voltages to supply the coupled devices. While in one embodiment, power converter 508 supplies power to MIC CPLD 502 physical layer device 506, network connector 504, in alternate embodiments, power converter 508 supplies power to the same and/or different devices.

MIC CPLD 502 draws power from the Power Converter 508 and contains functionalities to control and monitor MIC 500. The function of MIC CPLD 502 is to provide local logic to control the various parts of MIC 500. In one embodiment, MIC CPLD 502 provides control logic to read integrate voltage, power-on signal, status signals, etc. MIC CPLD 502 further reads card information from the Electrically Erasable Programmable Read Only Memory (EEPROM) (shown below). Information stored about MIC 500 in EEPROM is, but not limited to, card type, shell number, manufacture date, card revision number, and other manufacturing information. MIC CPLD 502 comprises software to read the various signals, in which the software is stored in MIC CPLD 502 at the time of manufacturing.

Physical layer device 506 is responsible for converting the received network signal to data frames and visa versa. For transmission, physical layer device 506 converts layer-1 data frames received from the main board into a signal appropriate for network connector 504 and forwards this signal to network connector 504. When MIC 500 receives network signals, physical layer device 506 takes the received network signal from network connector 504, digitizes the signals to create data frames and forwards the data frames to the main board 202.

Network connector 504 comprises physical interfaces that couple network element 200 to networks 206A-B. In one embodiment, network connector 504 may include copper, optical, and wireless interfaces such as 10/100 Base T Ethernet, 100 Base FX Ethernet, 1000 Base-T Ethernet, optical gigabit, 802.11, T-1, DS-3, OC-3/STS-1, OC-12/STS-3, etc. and/or combinations thereof.

MIC Interface connector 510 couples MIC 500 with main board 200. In one embodiment, interface connector is a coplanar female Champ connector with 200 pins that couples with a male Champ connector located on main board 200. Interface connector 504 includes data buses, control buses and small form pluggable definitions buses, as well as power and other control signals.

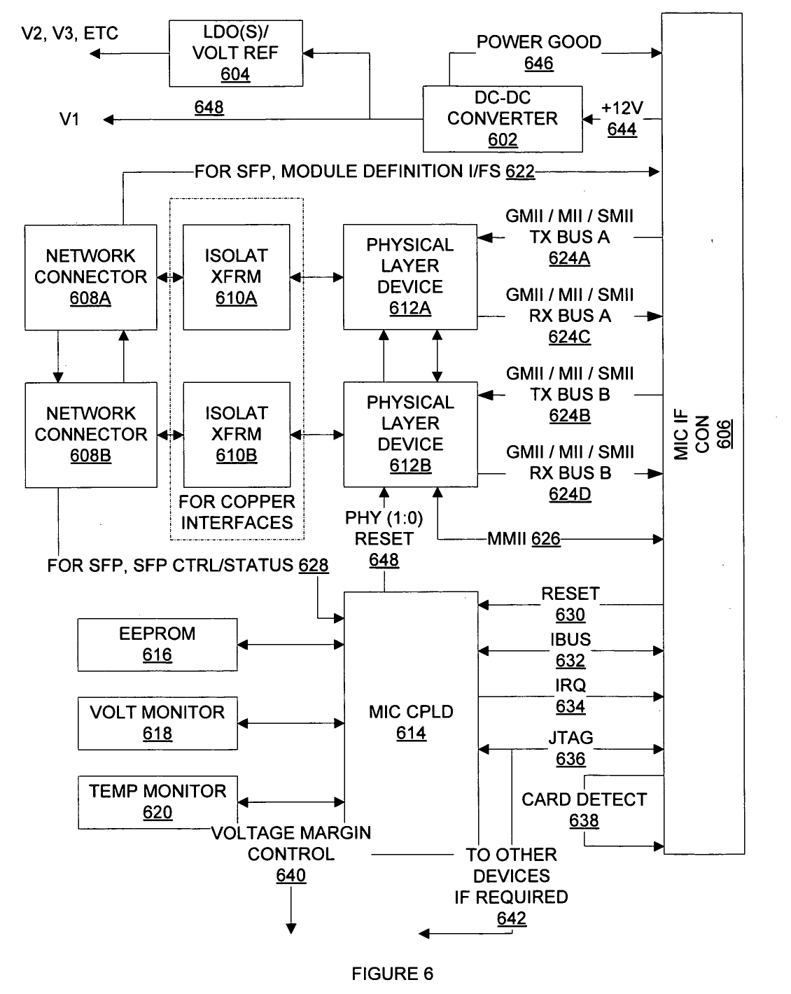

FIG. 6 is a block diagram illustrating a detailed MIC configuration 600 according to one embodiment of the invention. MIC 600 comprises DC-DC Converter 602, low dropout voltage regulator (LDO(s)), Voltage reference(s) 604, MIC interface connector 606, network connector 608A-B, isolation transformer 610A-B, physical layer device 612A-B, MIC CPLD 614, EEPROM 616, voltage monitor 618, and temperature monitor 620.

The power supply paths for interface connector 606 couple to DC-DC Converter 602 via +12 volt line 644. DC-DC converter receives the 12V input and makes available a primary voltage V1 648. LDO/voltage reference 604 couples to DC-DC converter 602 via 648 and outputs other voltages (V2, V3, etc) as required by the embodiment. A Power Good signal 646 from the DC-DC Converter 602 to the interface connector 606 allows the mainboard 202 to verify voltage status of 602.

MIC interface connector 606 further couples to physical layer device 612A-B via transmit bus 624A-B and receive bus 624C-D, respectively. Transmit and receive buses 624A-D transport the flow of data received and transmitted between physical layer device 612A-B and interface connector. The type of bus used can be any type of bus capable of supporting the transmit/receive speeds needed to support the physical connections available on MIC 600. While in one embodiment, transmit/receive bus 624A-D is media independent interface (MII) bus, in alternate embodiment, transmit/receive bus 624A-D may be a different bus type (gigabit media independent interface (GMII), serial media independent interface (SMII), etc.). Each bus is a configurable data path which is determined by the physical layer silicon (MII, GMII, SMII, etc.). Physical layer device 612A-B sends data over receive bus 624C-D through interface connector 606 to main board 202. Conversely, main board 202 forwards data to physical layer device 612A-B through interface connector 606 and over transmit bus 624A-B.

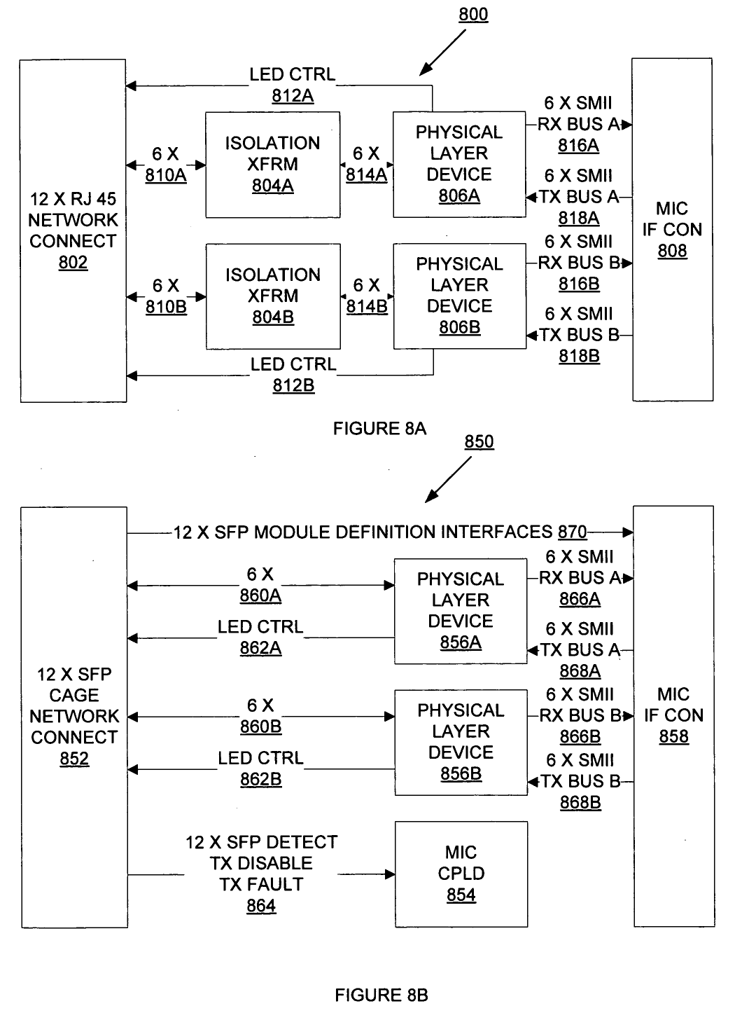

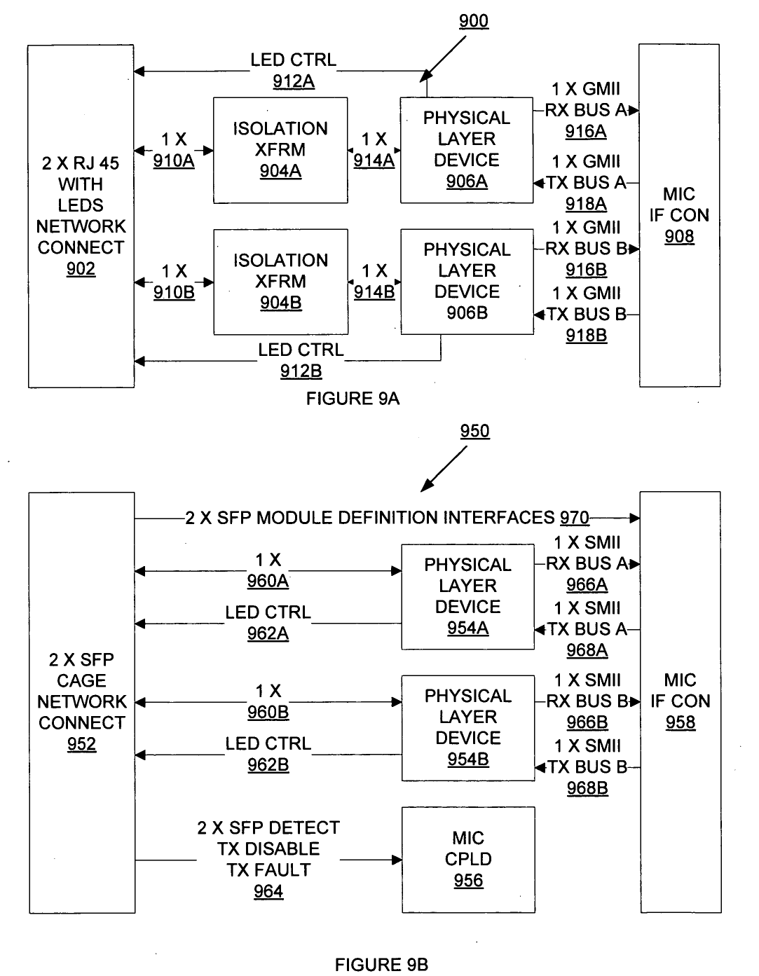

In one embodiment, physical layer device 612A-B further couples to network connector 608A-B. As is described below in FIGS. 8B and 9B, this embodiment supports optical network or wireless network connectors. While in one embodiment, network connector 608A-B is the physical connector used to coupled to a transmission line, such as a fiber coaxial cable, copper connector (RJ-45, etc.), etc., in alternate embodiments, network connector could be a wireless connections (radio, microwave, etc.). In an alternate embodiment, physical device layer 612A-B couples to network connector 608A-B via isolation transformer 610A-B. As shown below in FIGS. 8A and 9A, this embodiment supports network connectors with copper interfaces. In addition, physical layer devices 612A-B further couples to MIC interface connector 606 via a management media independent interface (MMII) 626. This interface is a control path interface that allows control interface to the physical layer silicon. MMII 626 allows control of the Ethernet physical layer silicon.

Network connector 608A-B further couples to MIC interface connector 606 and MIC CPLD 614 via module definition interface 622 and SFP Control/Status lines 628 respectively. Module definition interface 622 is a native control path interface to the Small form-factor pluggable (SFP) modules. SFP Control/Status lines 628 provide miscellaneous status and allow control to the MIC CPLD 614. A SFP module is a type of optical transceiver. SFP modules are hot-swappable and support speeds up to five gigabits per second.

MIC CPLD 614 is responsible for monitoring and overall control of the infrastructure core of MIC 600. The functions of the infrastructure core are, but not limited to, temperature sensor, monitoring MIC-generated voltages, margin control for MIC-generated voltages, controlling reset signals for each physical interface on MIC 600, monitoring SFP fault status, and monitoring SFP insertion/extraction status. MIC CPLD 614 couples to interface connector 606 via a series of control lines: reset line 630, iBus 632, Interrupt request lines (IRQ 634), and joint test action group (JTAG 636). Reset line 630 is the path used by main board 202 to send reset signal to MIC CPLD 614. After receiving a reset signal MIC CPLD 614 resets MIC 600. IRQ 636 is the interrupt request path that allows main board 202 to receive interrupt request from MIC CPLD 614. Physical Layer device 612A-B, network connector 608A-B, Voltage monitor 618 and Temp Monitor 620 are interrupt sources to the MIC CPLD. After receiving an interrupt request, MIC CPLD 614 forwards the interrupt to the main board 202. JTAG 636 is a standard for providing external test access to MIC 600. IBus 632 carries functional control information between MIC CPLD 614 and interface connector 606. MIC CPLD 614 receives temperature and voltage monitoring information from temperature monitor 620 and voltage monitor 618, with these monitors coupled to MIC CPLD 614. MIC CPLD 614 is further coupled to EEPROM 616. While in one embodiment, EEPROM 616 is serial EEPROM with size 4096 bits and organized as 512×8 or 256×16, in alternate embodiments, EEPROM may be different sizes and/or organized differently. EEPROM 616 stores the control software associated with the MIC type as well as the associated drivers and FPGA files. MIC CPLD 614 may further be coupled to voltage margin control via line 640.

In addition, MIC interface connector 606 includes card detect 638, which is a loopback interface used to physically detect when a MIC 600 is inserted into main board 202. In one embodiment, card detect 638 acts like a jumper, such that when the MIC card is not coupled, the card detect signal is false. On the other hand, when the MIC card is coupled, the card detect signal is true.

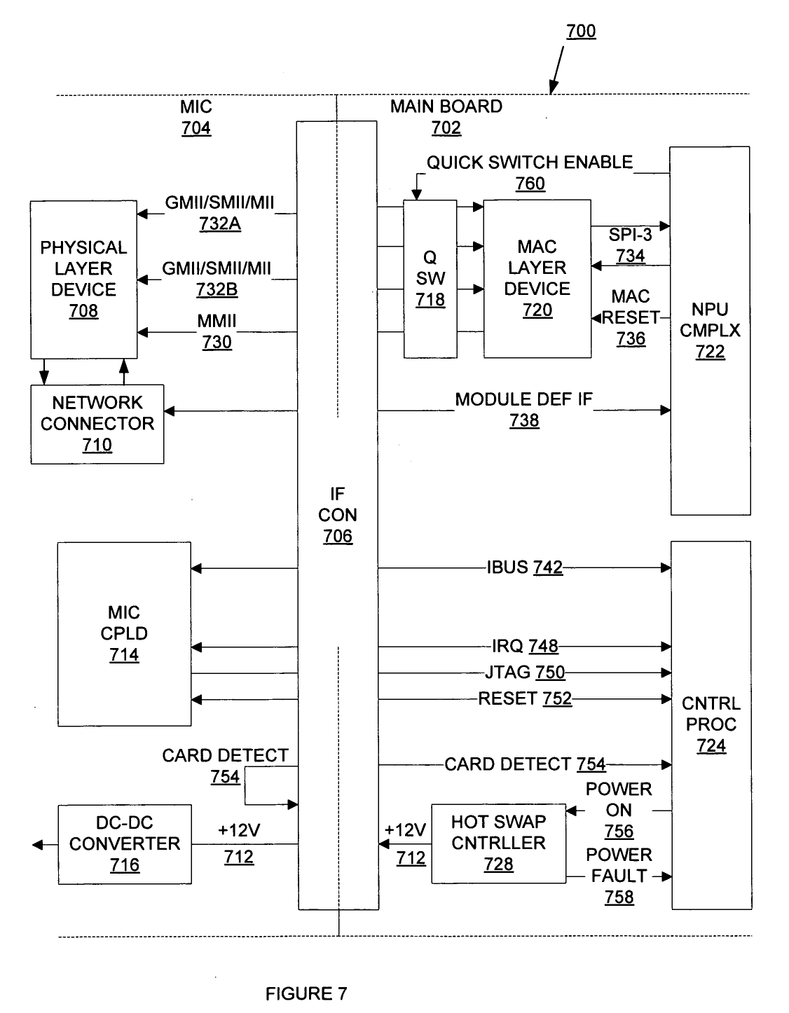

FIG. 7 is a block diagram of MIC 704 coupling with main board 702 via combined interface connector 706 according to one embodiment of the invention. In FIG. 7, main board 702 couples to MIC 704 via combined interface connector 706. Main board 702 comprises quick switch 718, MAC layer device 720, SLIP FPGA 722, control processor 724, Minnow 726, and Hot swap controller 728. MIC 704 comprises physical layer device 708, network connector 710, MIC CPLD 714, and DC-DC converter 716. Combined interface connector 706 restarts from the coupling of MIC interface connector and main board interface connector (e.g., MIC interface connector 308, main board interface connector 408). Once formed, combined interface connector allows the flow of signals, powers and information between main board 702 and MIC 704. While in one embodiment, combined interface connector 706 results from the coupling of a female Champ connector or MIC 704 with male Champ connector on main board 702, in alternate embodiments, combined interface connector results from the coupling of different connectors known in the art.

FIG. 7 further illustrates the individual pin connections used by interface connector 706 to couple functionality and data flow between MIC 704 and main board 702. In particular, across combined interface connector 706, physical layer device 708 couples to MAC layer device 720 and quick switch 718 across interface connector 706 via GMII/SMII/MII buses 732A-B and MMII 730 buses. MMII is a two wire serial interface that MAC layer device 720 uses to manage physical layer device 708 for the purposes of controlling and gathering status of physical layer device 708. Quick switch 718 provides electrical isolation during hot swap between the MAC Layer device 720 on the main board 702 and physical layer device 708 on MIC 704. MAC layer device 720 further couples to the NPU Complex 722 via MAC reset 736 and the SPI-3 bus 734. In addition, quick switch 718 couples to the NPU Complex 722 via quick switch enable 760. Quick switch enable 760 turns on/off the Quickswitch 718 and electrical isolates the MAC Layer Device from the IF Connector during hot swap.

NPU Complex 722 further couples across interface connector 706 to network connector 710 via Module Definition Interface 738. The NPU Complex 722 provides layer 2 and higher packet processing on the packet frames from the MAC Layer Device 720,

Control processor 724 couples to MIC CPLD 714 across interface connector 706 via six paths: IBUS 742, IRQ 748, JTAG 750, CARD DETECT 754 and reset 752. The control processor performs the hot swap control, MIC configuration, and upgrade of the MIC 704.

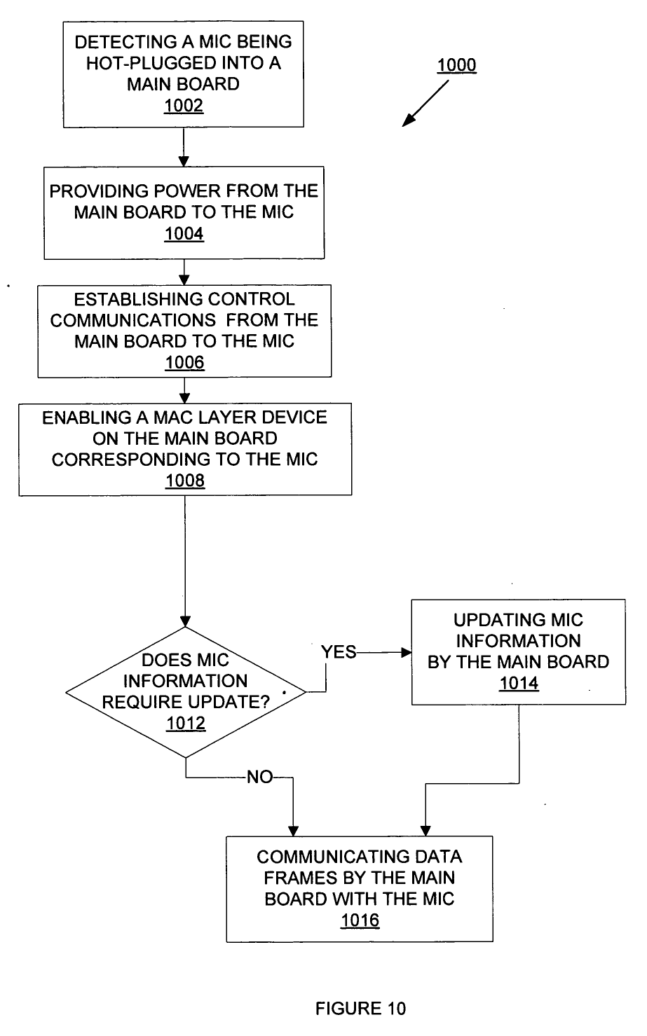

Control Processor 724 also controls the hot swapability of MIC 704 with main board 702. Control Processor 724 detects MIC 704 via card detect path 754. If MIC 704 decouples from main board 702, Control Processor 724 detects the decoupling via card detect path 754. Alternatively, Control Processor 724 detects a new MIC 704 coupling to main board 702 via card detect path 754. Control processor 724 starts up the procedure to handle the change in hardware as further described in FIG. 10.

Control Processor 724 further controls the hot swapping of MIC 704 via hot swap controller 728. Hot swap controller 728 and Control Processor 724 couple via power on 756 and power fault 758 paths. The Hot Swap Controller 728 controls the +12V 712 power to the Interface Connector 706. When the MIC is decoupled, Control Processor 724 will turn off +12V 712 power by the Power On 756 signal to the Hot Swap Controller 728. When the MIC 704 is coupled, Control Processor 724 will turn on +12V power by the Power On 756 signal to the Hot Swap Controller 728. Power Fault 758 provides indication to the Control Processor that the +12V 712 power to the MIC 704 did not correctly turn on hence indicating a fault condition.

FIGS. 8A-B and 9A-B illustrate different physical connectors for a MIC. FIG. 8A is a block diagram illustrating one example of MIC 800 with 10/100 Ethernet RJ 45 connectors according to one embodiment of the invention. While in one embodiment, MIC 800 has twelve 10/100 Base T ports . . . MIC 800 supports auto-detection and software configure of port speed as well as auto-negotiation for duplex mode and polarity. In FIG. 8A, MIC 800 comprises interface connector 808, physical layer device 806A-B, isolation transformer 804A-B and 10/100 Ethernet RJ 45 connectors 802. Interface connector 808 couples to physical layer device 806A-B via six wide SMII transmit 818A-B and receive 816A-B bus. Physical layer device further couples to isolation transformer 804A-B via six wide paths 814A-B. Isolation transformers which in turn couple to 10/100 Ethernet RJ 45 connectors 802 six wide paths 810A-B. Physical layer device further couples to LED control paths 812A-B. LED control paths 812A-B allow for control of the LEDs that indicate activity, link speed, and link activity.

10/100 Ethernet RJ 45 connectors 802 receive signals from attached devices via copper cable and forwards the signals to isolation transformer 804A-B. Isolation transformer 804A-B conditions the signals and forwards the signal to physical layer device 806A-B. Physical layer device 806A-B converts the signal into layer 1 frames, which are transmitted to main board 202 via MIC interface connector 808 over six wide SMII receive bus 816A-B. Main board 202 processes the received layer 1 frames.

When MIC 800 transmits out of 10/100 Ethernet RJ 45 connectors 802, main board 202 forwards layer 1 data frames via MIC interface connector 808 to physical layer device 806A-B over six wide SMII transmit bus 818A-B. Physical layer device 806A-B converts the layer 1 data frames into network signal and forwards the network signal to isolation transformer 804A-B. Isolation transformer 804A-B conditions the signal for transmittance and forwards the conditioned signal to 10/100 Ethernet RJ 45 connectors 802. 10/100 Ethernet RJ 45 connectors 802, transmit the signal to the coupled network via one or more of the 10/100 Ethernet copper ports.

FIG. 8B is a block diagram illustrating one example of MIC 850 with 10/100 Ethernet SFP Cage connectors 852 according to one embodiment of the invention. In one embodiment, MIC 850 has twelve slots for SFP optical ports in alternate embodiments, MIC 850 have more or less SFP optical ports. Each slot can be loaded with a 100Base-FX SFP module. MIC 850 supports hot swappable SFP transceivers, transmit disable control, transmit fault detection, SFP detection and module identification of each SFP. Furthermore, MIC 850 supports link and activity status for each SFP port. In FIG. 8B, MIC 850 comprises interface connector 858, physical layer device 856A-B, MIC CPLD 854, and 10/100 Ethernet SFP CAGE connectors 852. Interface connector 858 couples to physical layer device 856A-B via six wide SMII transmit 868A-B and receive 866A-B bus. Physical layer device further couples to 10/100 Ethernet SFP CAGE connectors 852 via six wide paths 860A-B and LED control paths 862A-B. LED control paths 862A-B allow for control of the LEDs that indicate activity, link speed, and link activity. MIC CPLD 854 couples to 10/100 Ethernet SFP CAGE connectors 852 via twelve wide SFP detect/transmit/transmit fault paths 864. SFP detect/transmit/faults path 864 carry information that detect a SFP, control the transmitter on/off of a SPF and when a particular SFP exhibits a fault. Interface connector 858 further couples to 10/100 Ethernet SFP CAGE connectors 852 via twelve wide SFP module definition interface 870. SFP module definition interface 870 allows for the mainboard 202 to read the SFP's EEPROM and diagnostics information.

10/100 Ethernet SFP CAGE connectors 852 receive signals from attached devices via fiber optic cable and forwards the signals to physical layer device 856A-B. Physical layer device 856A-B converts the signal into layer 1 frames, which are transmitted to main board 202 via interface connector 858 over six wide SMII receive bus 866A-B. Main board 202 processes the received layer 1 frames.

When MIC 850 transmits data out of 10/100 Ethernet SFP CAGE connectors 852, main board 202 forwards layer 1 data frames via interface connector to physical layer device 856A-B over six wide SMII transmit bus 868A-B. Physical layer device 856A-B converts the layer 1 data frames into network signal and forwards the network signal to 10/100 Ethernet SFP CAGE connectors 852. 10/100 Ethernet SFP CAGE connectors 852, in turn, transmit the signal to the coupled network via one or more of the 10/100 Ethernet optical ports.

FIG. 9A is a block diagram illustrating one example of MIC 900 with 1000 Ethernet RJ 45 connectors according to one embodiment of the invention. While in one embodiment, MIC 900 has two 1000 Base T ports in alternated embodiments, MIC 900 support more or less ports. MIC 900 supports auto-detection and software configure of port speed as well as auto-negotiation for duplex mode and polarity. In FIG. 9A, MIC 900 comprises interface connector 908, physical layer device 906A-B, isolation transformer 904A-B and 1000 Ethernet RJ 45 connectors 902. Interface connector 908 couples to physical layer device 906A-B via one wide GMII transmit 918A-B and receive 916A-B bus. Physical layer device further couples to isolation transformer 904A-B via one wide path 914A-B Isolation transformers which in turn couple to 1000 Ethernet RJ 45 connectors 902 one wide path 910A-B. LED control paths 912A-B also couple to 1000 Ethernet RJ 45 connectors 902 and Physical layer device 906A-B. LED control paths 912A-B allow for control of the LEDs that indicate activity, link speed, and link activity.

1000 Ethernet RJ 45 connectors 902 receive signals from attached devices via copper cable and forwards the signals to isolation transformer 904A-B. Isolation transformer 904A-B conditions the signals and forwards the signal to physical layer device 906A-B. Physical layer device 906A-B converts the signal into layer 1 frames, which are transmitted to main board 202 via interface connector 908 over one wide GMII receive bus 916A-B. Main board 202 processes the received layer 1 frames.

When MIC 900 transmits out of 1000 Ethernet RJ 45 connectors 902, main board 202 forwards layer 1 data frames via interface connector to physical layer device 906A-B over one wide GMII transmit bus 918A-B. Physical layer device 906A-B converts the layer 1 data frames into network signal and forwards the network signal to isolation transformer 904A-B. Isolation transformer 904A-B conditions the signal for transmittance and forwards the conditioned signal to 1000 Ethernet RJ 45 connectors 902. 1000 Ethernet RJ 45 connectors 902, in turn, transmit the signal to the coupled network via one or more of the 1000 Ethernet copper ports.

FIG. 9B is a block diagram illustrating one example of MIC 950 with 1000 Ethernet SFP Cage connectors 952 according to one embodiment of the invention. While in one embodiment, MIC 950 has two slots for SFP optical ports, in alternate embodiments, MIC 950 support more or less SFP optical ports. Each slot can be loaded with a 1000Base-SX, 1000Base-LX or 1000Base-ZX SFP modules. MIC 950 supports hot swappable SFP transceivers, transmit disable control, transmit fault detection, SFP detection and module identification of each SFP. Furthermore, MIC 950 supports link and activity status for each SFP port. In FIG. 9B, MIC 950 comprises interface connector 958, physical layer device 954A-B, MIC CPLD 956, and 1000 Ethernet SFP CAGE connectors 952. Interface connector 958 couples to physical layer device 956A-B via one wide GMII transmit 966A-B and receive 968A-B bus. Physical layer device further couples to 1000 Ethernet SFP CAGE connectors 952 via one wide path 960A-B and LED control paths 962A-B. LED control path 962A-B control the on/off of the link/activity status LEDs in the SFP cage 952. MIC CPLD 956 couples to 1000 Ethernet SFP CAGE connectors 952 via two wide SFP detect/transmit/transmit fault paths 964. SFP detect/transmit/faults path 964 carries information that detects an SFP, when a particular SFP is transmitting a signal, and/or if a particular SFP exhibits a fault. Interface connector 958 further couples to 1000 Ethernet SFP CAGE connectors 952 via two wide SFP module definition interface 970. SFP module definition interface 970 allows for the mainboard 202 to read the SFP EEPROM and diagnostics information.

1000 Ethernet SFP CAGE connectors 952 receive signals from attached devices via fiber optic cable and forward the signals to physical layer device 954A-B. Physical layer device 954A-B converts the signal into layer 1 frames, which are transmitted to main board 202 via interface connector 958 over one wide GMII receiver bus 966A-B. Main board 202 processes the received layer 1 frames.

When MIC 950 transmits data out of 1000 Ethernet SFP CAGE connectors 952, main board 202 forwards layer 1 data frames via interface connector to physical layer device 954A-B over one wide GMII transmit bus 968A-B. Physical layer device 954A-B converts the layer 1 data frames into network signal and forwards the network signal to 1000 Ethernet SFP CAGE connectors 952. 1000 Ethernet SFP CAGE connectors 952, in turn, transmit the signal to the coupled network via one or more of the 1000 Ethernet optical ports.

FIG. 10 is a flow diagram illustrating a process 1000 of hot-plugging a MIC onto a Main Board, according to one embodiment of the invention. In FIG. 10, at block 1002, process 1000 detects a MIC being hot-plugged into the main board. In one embodiment, process 1000 detects the insertion of a MIC into the main board by voltage passing through the card detect pins of the interface connector as illustrated in FIG. 6.

At block 1004, process 1000 provides power to the newly inserted MIC from the main board. In one embodiment, main board allows the flow of voltage from main board to MIC via Control processor 724 and hot swap controller 728.

At block 1006, process 1000 establishes control communications from the main board to the inserted MIC. In one embodiment, main board communicates to the MIC CPLD and EEPROM to determine the card type via IBUS 632.

At block 1008, process 1000 enables the MAC layer device and NPU Complex on the main board corresponding to the newly inserted MIC. While in one embodiment, there is one MAC layer device for each inserted MIC, in alternate embodiments, there can be more or less MAC layer devices for each inserted MIC.

At block 1012, process 1000 determines if the MIC information requires an update. The MIC information could need an update because there is an update to the MIC firmware available. If the MIC card information needs to be updated, main board updates the information at block 1014. Process 1000 updates the EEPROM on the MIC from the mainboard via the IBUS bus.

At block 1016, process 1000 communicates data frames between the main board and the MIC. In one embodiment, process 1000 communicates data frames as in described in FIGS. 2-4.

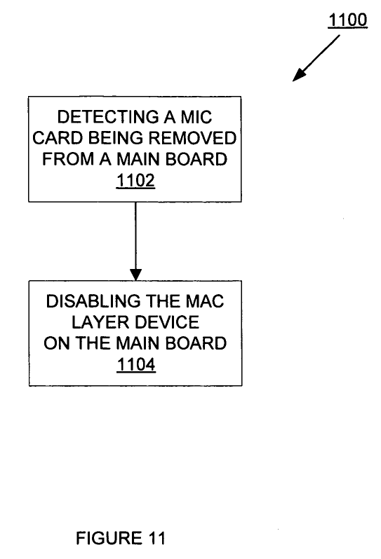

FIG. 11 is a flow diagram illustrating a process 1100 for hot-unplugging a MIC from a main board, according to one embodiment of the invention. In FIG. 11, at block 1102, process 1100 detects a MIC being removed from the main board. While in one embodiment, process detects the MIC removal by detecting a disruption of signal across card detect path (as illustrated in FIG. 7). At block 1104, process 1100 disables MAC layer device, turns off power using the hot swap controller and isolates the buses by disabling the quickswitch functionality associated with the MIC. While in one embodiment, process 1100 disable the MAC layer device associated with the MIC, in alternate embodiments, process 1100 disables part of the MAC layer device and/or more than one MAC layer device associated with the MIC.

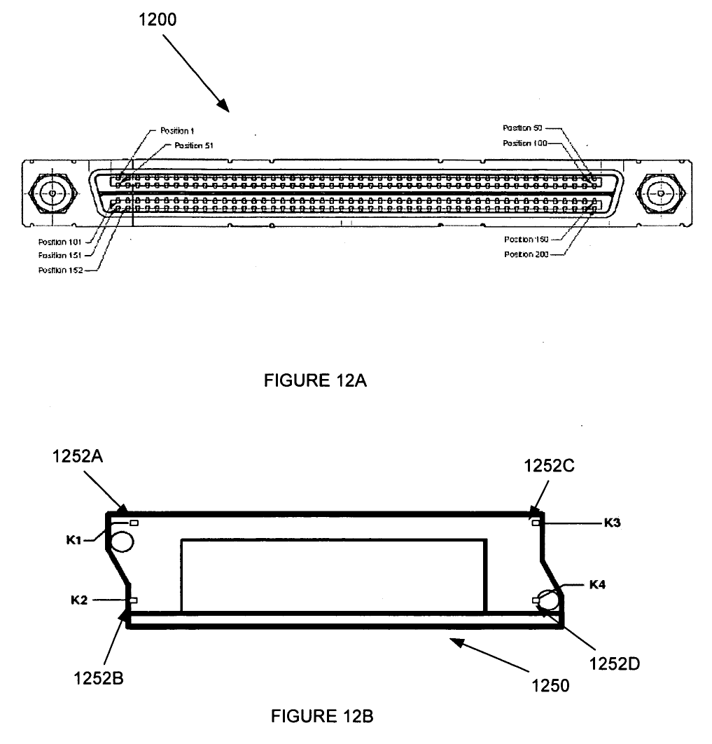

FIG. 12A is an illustration of MIC interface connector 1200, according to one embodiment of the invention. In FIG. 12, interface connector 1200 is a 200 pin connector. Pins 1-100 are on the top two rows, while pins 101-200 are in the bottom two rows of pins. Across these pins carries the paths as illustrated in FIGS. 6-9.

FIG. 12B is an illustration of the key arrangement 1252A-D for a MIC 1250. In FIG. 12B, MIC 1250 comprises four blocking keys 1252A-D. In one embodiment, blocking keys 1252A-D are used to permit successful MIC insertion into the main board. This allows MIC associated with the main board to be inserted into the main board, preventing foreign cards for accidentally attached to the main board. In one embodiment, blocking keys 1252A-D are part of the MIC sheet metal. If present each key 1252A-D has the proper chassis gap to allow successful insertion into the main board. Use of these keys 1252A-D allows the MIC design to support future MICs that may not be supported by one version of main board.

A hot-swappable multi-configuration network service system has been described herein. Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments of the present invention also relate to an apparatus for performing the operations herein. This apparatus may be specially constructed for the required purposes, or it may comprise a general-purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs), erasable programmable ROMs (EPROMs), electrically erasable programmable ROMs (EEPROMs), magnetic or optical cards, or any type of media suitable for storing electronic instructions, and each coupled to a computer system bus.

The algorithms and displays presented herein are not inherently related to any particular computer or other apparatus. Various general-purpose systems may be used with programs in accordance with the teachings herein, or it may prove convenient to construct more specialized apparatus to perform the required method operations. The required structure for a variety of these systems will appear from the description below. In addition, embodiments of the present invention are not described with reference to any particular programming language. It will be appreciated that a variety of programming languages may be used to implement the teachings of embodiments of the invention as described herein.

A machine-readable medium may include any mechanism for storing or transmitting information in a form readable by a machine (e.g., a computer). For example, a machine-readable medium includes read only memory (“ROM”); random access memory (“RAM”); magnetic disk storage media; optical storage media; flash memory devices; electrical, optical, acoustical or other form of propagated signals (e.g., carrier waves, infrared signals, digital signals, etc.); etc.

In the foregoing specification, embodiments of the invention have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. A media interface card of a network element, comprising:
a network connector capable of being coupled to a client over a network;
an interface connector capable of being coupled to a main board; and
a physical layer device coupled to the network connector and the interface connector to perform Physical Layer transformation on network traffic passing between the network connector and the interface connector,
wherein the media interface card is hot-swappable from the main board and the main board to perform at least Media Access Control Layer transformation to the network traffic.

2. The media interface card of claim 1, wherein the network traffic comprises:
a first plurality of network signals received from the client through the network connector;
a first plurality of data frames transformed from the first plurality of network signals by the physical layer device and transmitted to the main board through the interface connector;
a second plurality of data frames received from the main board through the interface connector; and
a second plurality of network signals transformed from the second plurality of data frames by the physical layer device and transmitted to the client through the network connector.

3. The media interface card of claim 2, further comprising an isolation transformer coupled to the network connector and the physical layer device, wherein the isolation transformer transforms the first plurality of network signals and the second plurality of network signals to different formats.

4. The media interface card of claim 1, further comprising an infrastructure control device coupled to the physical layer device and the main board, wherein the infrastructure control device communicates status and control messages of the physical layer device with the main board through the interface connector.

5. The media interface card of claim 4, wherein the infrastructure control device comprises an Electrically Erasable Programmable Read Only Memory (EEPROM) to store device information, a voltage monitor to monitor power voltages, a temperature monitor to monitor internal temperature, and a Small Form-factor Pluggable (SFP) device monitor to monitor status of SFP devices.

6. The media interface card of claim 5, wherein information within the EEPROM can be updated by the main board through the interface connector.

7. The media interface card of claim 1, wherein the network connector comprises a Small Form-factor Pluggable device capable of being hot-swapped from the network connector.

8. The media interface card of claim 1, further comprising a power converter coupled to the physical layer device, wherein the power converter converts electronic power received from the main board to a plurality of voltages.

9. The media interface card of claim 1, further comprising a blocking key coupled to a chassis gap on the main board, wherein the blocking key prevents the media interface card from incompatibly plugging into the main board.

10. A main board of a network element, comprising:
an interface connector capable of being coupled to a media interface card hot-swappable from the main board; and
a Media Access Control (MAC) layer device coupled to the interface connector to perform MAC Layer transformation on network traffic received from or transmitted to the media interface card through the interface connector,
wherein the media interface card is capable of performing Physical Layer transformation and depends on the main board to perform at least the MAC Layer transformation to the network traffic.

11. The main board of claim 10, wherein the network traffic comprises:
a first plurality of data frames received from the media interface card through the interface connector, and transformed by the MAC layer device to a first plurality of data packets; and
a second plurality of data frames transformed by the MAC layer device from a second plurality of data packets, and sent to the media interface card through the interface connector.

12. The main board of claim 11, further comprising a quick switch device coupled to the MAC layer device and a physical layer device of a media interface card, wherein the quick switch provides electrical isolation during hot swapping.

13. The main board of claim 11, further comprising a NPU Complex coupled to the MAC layer device to perform higher layer processing of data packets from the media interface card.

14. The main board of claim 10, wherein the MAC layer device can be enabled when the media interface card is plugged into the main board, and can be disabled when the media interface card is unplugged from the main board.

15. The main board of claim 10, further comprising a hot-swap controller coupled to the interface connector, wherein the hot-swap controller supplies power to the media interface card through the interface connector.

16. The main board of claim 10, further comprising a control processor coupled to the interface connector, wherein the control processor communicates status and control messages with the media interface card through the interface connector.

17. The main board of claim 16, wherein information within an infrastructure control device of the media interface card can be updated by the control processor.

18. The main board of claim 10, further comprising a chassis gap coupled to a blocking key of a compatible media interface card, wherein the chassis gap enables the compatible media interface card to be plugged into the main board.

19. A network element, comprising:
a media interface card, the media interface card comprises:
a network connector capable of being coupled to a client over a network,
a first interface connector, and
a physical layer device coupled to the network connector and the interface connector to perform Physical Layer transformation on network traffic passing between the network connector and the first interface connector; and
a main board, the main board comprises:
a second interface connector capable of being coupled to the first interface connector of the media interface card, and
a Media Access Control (MAC) layer device coupled to the second interface connector to perform MAC Layer transformation on the network traffic received from and transmitted to the media interface card through the second interface connector,
wherein the media interface card is hot-swappable from the main board and depends on the main board to perform at least the MAC Layer transformation to the network traffic.

20. The network element of claim 19,
wherein the media interface card further comprises:
a power converter coupled to the physical layer device to convert electronic power received from the main board to a plurality of voltages, and
an infrastructure control device coupled to the physical layer device to communicate status and control messages with the main board,
wherein the main board further comprises:
a hot-swap controller coupled to the second interface connector to supply power to the media interface card, and
a control processor coupled to the second interface connector to communicate the status and control messages with the media interface card.
